(19) United States
(12) Patent Application Publication
(10) Pub. No.: US 2026/0215167 A1
(43) Pub. Date: Jul. 23, 2026

(54) MAGNETIC MEMORY DEVICE

(71) Applicant: Kioxia Corporation, Tokyo (JP)

(72) Inventors: Kenichi YOSHINO, Seongnam-si Gyeonggi-do (KR); Tadaaki OIKAWA, Seoul (KR); Kazuya SAWADA, Seoul (KR); Naoki AKIYAMA, Seoul (KR); Takuya SHIMANO, Seoul (KR); Hyungjun CHO, Seoul (KR)

(73) Assignee: Kioxia Corporation, Tokyo (JP)

(21) Appl. No.: 19/566,641

(22) Filed: Mar. 13, 2026

Related U.S. Application Data
(62) Division of application No. 18/466,727, filed on Sep. 13, 2023.

(30) Foreign Application Priority Data
Sep. 16, 2022 (JP) 2022-148395

(51) Int. Cl. H10N 50/85; G11C 11/16; H10B 61/00; H10N 50/10

(52) U.S. Cl. CPC H10N 50/85; G11C 11/161; H10B 61/00; H10N 50/10

(57) ABSTRACT

A method of manufacturing a magnetic memory device includes: forming a first structure including a first wiring line extending in a first direction, the first wiring line including a first conductive layer and a second conductive layer provided on the first conductive layer and formed of a material containing carbon (C); forming a stacked layer in which a magnetoresistance effect element layer and a switching element layer are stacked, on the first structure; forming a magnetoresistance effect element and a switching element by etching the magnetoresistance effect element layer and etching the switching element layer; and forming a second wiring line extending in a second direction intersecting the first direction, on a second structure including the magnetoresistance effect element and the switching element.

### CROSS-REFERENCE TO RELATED APPLICATIONS

This application is a Divisional of U.S. Application No. 18/466,727, filed September 13, 2023, which is based upon and claims the benefit of priority from Japanese Patent Application No. 2022-148395, filed September 16, 2022, the entire contents of all of which are incorporated herein by reference.

### FIELD

Embodiments described herein relate generally to a magnetic memory device.

### BACKGROUND

A magnetic memory device has been proposed in which a plurality of memory cells each including a magnetoresistance effect element and a selector (switching element) are integrated on a semiconductor substrate.

### BRIEF DESCRIPTION OF THE DRAWINGS

FIG. 1 is a perspective view schematically showing a basic configuration of a magnetic memory device according to an embodiment.

FIGS. 2A and 2B each are a cross-sectional view schematically showing a detailed configuration of the magnetic memory device according to the embodiment.

FIG. 3 is a cross-sectional view schematically showing a basic configuration of a magnetoresistance effect element of the magnetic memory device according to the embodiment.

FIG. 4 is a cross-sectional view schematically showing a basic configuration of a selector of the magnetic memory device according to the embodiment.

FIG. 5 is a schematic diagram showing current-voltage characteristics of the selector of the magnetic memory device according to the embodiment.

FIGS. 6A and 6B each are a cross-sectional diagram schematically illustrating a part of a method of manufacturing the magnetic memory device according to the embodiment.

FIGS. 7A and 7B each are a cross-sectional diagram schematically illustrating a part of the method of manufacturing the magnetic memory device according to the embodiment.

FIGS. 8A and 8B each are a cross-sectional diagram schematically illustrating a part of the method of manufacturing the magnetic memory device according to the embodiment.

FIGS. 9A and 9B each are a cross-sectional diagram schematically illustrating a part of the method of manufacturing the magnetic memory device according to the embodiment.

FIGS. 10A and 10B each are a cross-sectional diagram schematically illustrating a part of the method of manufacturing the magnetic memory device according to the embodiment.

FIGS. 11A and 11B each are a cross-sectional diagram schematically illustrating a part of the method of manufacturing the magnetic memory device according to the embodiment.

FIGS. 12A and 12B each are a cross-sectional diagram schematically illustrating a part of the method of manufacturing the magnetic memory device according to the embodiment.

FIGS. 13A and 13B each are a cross-sectional diagram schematically illustrating a part of the method of manufacturing the magnetic memory device according to the embodiment.

FIGS. 14A and 14B each are a cross-sectional diagram schematically illustrating a part of the method of manufacturing the magnetic memory device according to the embodiment.

FIGS. 15A and 15B each are a cross-sectional diagram schematically illustrating a part of the method of manufacturing the magnetic memory device according to the embodiment.

### DETAILED DESCRIPTION

In general, according to one embodiment, a magnetic memory device includes: a first wiring line extending in a first direction; a second wiring line provided on an upper layer side of the first wiring line and extending in a second direction intersecting the first direction; and a memory cell provided between the first wiring line and the second wiring line and including a magnetoresistance effect element and a switching element which are stacked in a third direction intersecting the first direction and the second direction, wherein the first wiring line includes a first conductive layer and a second conductive layer provided on the first conductive layer and formed of a material containing carbon (C).

Embodiments will be described hereinafter with reference to the accompanying drawings.

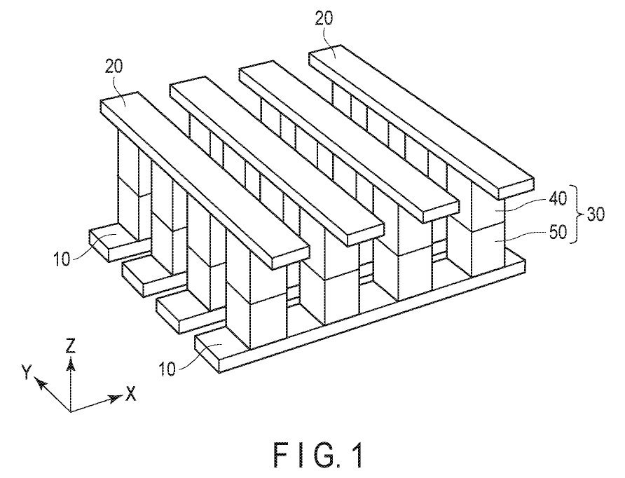

FIG. 1 is a perspective view schematically showing a basic configuration of a magnetic memory device according to an embodiment.

The magnetic memory device shown in FIG. 1 is provided on a lower structure (not shown) including a semiconductor substrate (not shown) and includes a plurality of first wiring lines 10, a plurality of second wiring lines 20 and a plurality of memory cells 30.

The first wiring lines 10 extend in an X direction and correspond to word lines, respectively. The second wiring lines 20 are provided on an upper layer side of the first wiring lines 10 and extend in a Y direction. The second wiring lines 20 correspond to bit lines, respectively.

The memory cells 30 are provided between the first wiring lines 10 and the second wiring lines 20 and each include a magnetoresistance effect element 40 and a selector (switching element) 50 connected in series. More specifically, the magnetoresistance effect element 40 and the selector 50 are stacked in a Z direction, and the selector 50 is provided on a lower layer side of the magnetoresistance effect element 40.

Note that the X direction, the Y direction and the Z direction mutually intersect each other. More specifically, the X direction, the Y direction and the Z direction are orthogonal to each other.

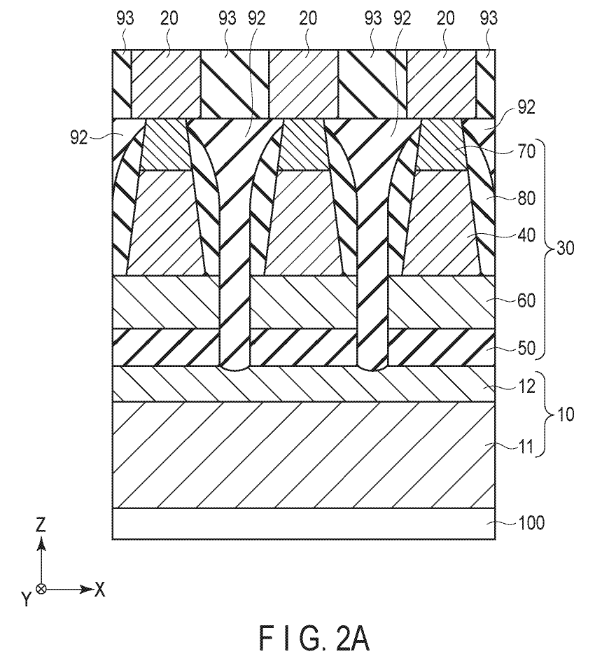

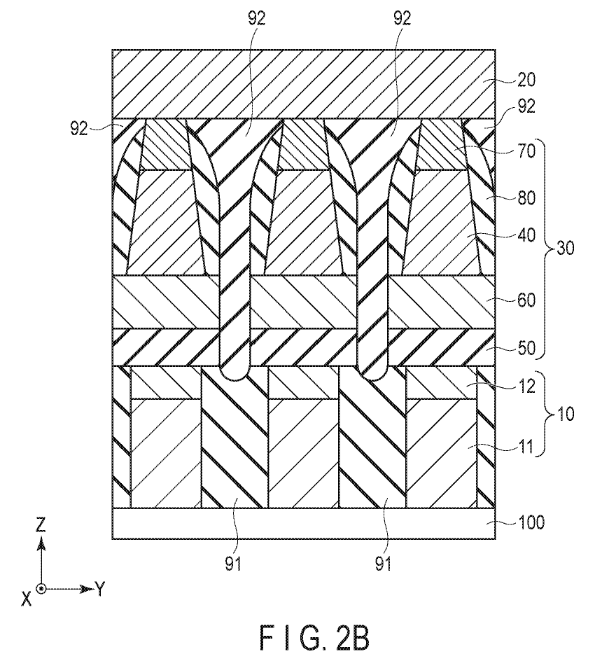

FIGS. 2A and 2B are cross-sectional views schematically showing a more detailed configuration of the magnetic memory device of this embodiment. FIG. 2A is a cross-sectional view parallel to the X direction, and FIG. 2B is a cross-sectional view parallel to the Y direction.

As shown in FIGS. 2A and 2B, on a lower structure 100 including a semiconductor substrate (not shown), first wiring lines 10, second wiring lines 20, memory cells 30 and interlayer insulating layers 91, 92 and 93 are provided.

The first wiring lines 10 each include a first conductive layer 11 and a second conductive layer 12 provided on the first conductive layer 11. As shown in FIG. 2B, the pattern of the first conductive layer 11 and the pattern of the second conductive layer 12 as viewed from the X direction are aligned with each other.

The resistivity of the first conductive layer 11 is lower than that of the second conductive layer 12 and is formed of a metal material containing a metal element. Specifically, the first conductive layer 11 is formed of a metal material containing tungsten (W) or copper (Cu). More specifically, the first conductive layer 11 is formed from a tungsten (W) layer or a copper (Cu) layer. In this embodiment, a W layer is used as the first conductive layer 11.

The second conductive layer 12 is formed of a material containing carbon (C). Specifically, the second conductive layer 12 is formed from a carbon layer containing substantially only carbon. Note that such an expression as “substantially containing only carbon” means that it is allowed to contain an unintended impurity other than carbon.

The memory cells 30 each include a magnetoresistance effect element 40, a selector (switching element) 50, a middle electrode 60, a hard mask 70 and a sidewall insulating layer 80.

FIG. 3 is a cross-sectional view schematically showing a basic configuration of the magnetoresistance effect element 40.

The magnetoresistance effect element 40 includes a storage layer (first magnetic layer) 41, a reference layer (second magnetic layer) 42 and a tunnel barrier layer (nonmagnetic layer) 43.

The storage layer 41 is a ferromagnetic layer having a variable magnetization direction. The variable magnetization direction means that the magnetization direction changes for a given write current. The reference layer 42 is a ferromagnetic layer having a fixed magnetization direction. The fixed magnetization direction means that the magnetization direction does not change for a given write current. The tunnel barrier layer 43 is an insulating layer provided between the storage layer 41 and the reference layer 42.

When the magnetization direction of the storage layer 41 is parallel to that of the reference layer 42, the magnetoresistance effect element 40 exhibits a low resistance state. When the magnetization direction of the storage layer 41 and the magnetization direction of the reference layer 42 are antiparallel to each other, the magnetoresistance effect element 40 exhibits a high resistance state in which the resistance thereof is higher than the resistance of the low resistance state. Therefore, the magnetoresistance effect element 40 can store binary data according to its resistance state.

The magnetoresistance effect element 40 is a spin transfer torque (STT) type magnetoresistance effect element and has perpendicular magnetization. That is, the magnetization direction of the storage layer 41 is perpendicular to its main surface, and the magnetization direction of the reference layer 42 is perpendicular to its main surface.

Note that in this embodiment, a bottom-free type magnetoresistance effect element, in which the storage layer 41 is located on the lower layer side of the reference layer 42, is employed, but a top-free type magnetoresistance effect element, in which the storage layer 41 is located on the upper layer side of the reference layer 42, may as well be used.

FIG. 4 is a cross-sectional view schematically showing a basic structure of the selector 50.

The selector 50 includes a bottom electrode 51, a top electrode 52 and a selector material layer (switching material layer) 53. Note that each first wiring line 10 may be used as the bottom electrode of the selector 50 without providing the bottom electrode 51. In this embodiment, the first wiring lines 10 each serve as the bottom electrode 51 of the respective selector 50. Further, for the top electrode 52 of the selector 50, the middle electrode 60, which will be described later, is used.

The selector material layer 53 has insulating properties. The selector material layer 53 is formed of, for example, an insulator that is mainly composed of silicon oxide, contains SiO2 or a material formed substantially of SiO2, and contains a dopant introduced by ion implantation. The dopants contains, for example, arsenic (As) or germanium (Ge).

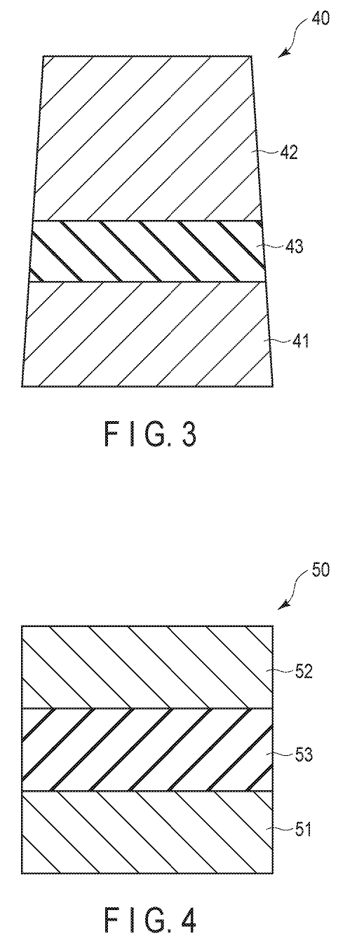

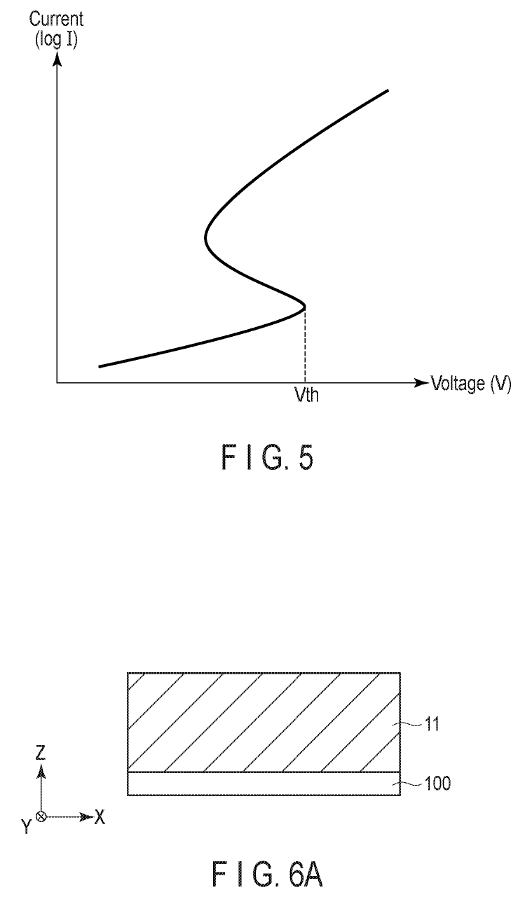

As the selector material layer 53, a 2-terminal switching element having characteristics in which the resistance drops sharply at a certain voltage, the applied voltage drops sharply accordingly and the current increases (snapback characteristics) is described as an example, the operation of which will be described later with reference to FIG. 5. The material used for the switching element having such characteristics is appropriately selected according to the characteristics of the memory cell.

FIG. 5 is a diagram schematically illustrating the current-voltage characteristics of the selector 50.

As shown in FIG. 5, the selector 50 has characteristics that when the voltage applied between the two terminals (between the bottom electrode 51 and the top electrode 52) becomes equal to or higher than a threshold voltage Vth, it changes from an off state to an on state.

When a voltage is applied between the first wiring line 10 and the second wiring line 20 and a voltage greater than or equal to the threshold voltage Vth is applied between the bottom electrode 51 and the top electrode 52 of the selector 50, the selector 50 changes from the off state to the on state. As a result, current flows to the magnetoresistance effect element 40 connected in series with the selector 50, thereby enabling writing to or reading from the magnetoresistance effect element 40.

Let us now return to the explanation of FIGS. 2A and 2B.

Between the magnetoresistance effect element 40 and the selector 50, the middle electrode 60 is provided. The middle electrode 60 is formed of a material containing carbon (C). Specifically, the middle electrode 60 is formed from a carbon layer containing substantially only carbon (C). The middle electrode 60 functions as the bottom electrode of the magnetoresistance effect element 40 and also as the top electrode of the selector 50(, which corresponds to the top electrode 52 shown in FIG. 4).

The hard mask 70 formed of metal material is provided on the magnetoresistance effect element 40. The hard mask 70 functions as, in addition to as a mask for patterning the magnetoresistance effect element 40, also functions as the top electrode of the magnetoresistance effect element 40.

The sidewall insulating layer 80 is provided on a side surface of the magnetoresistance effect element 40 and a side surface of the hard mask 70. The sidewall insulating layer 80 functions as a protective layer for the magnetoresistance effect element 40.

Next, a method of manufacturing the magnetic memory device according to the embodiment will be described.

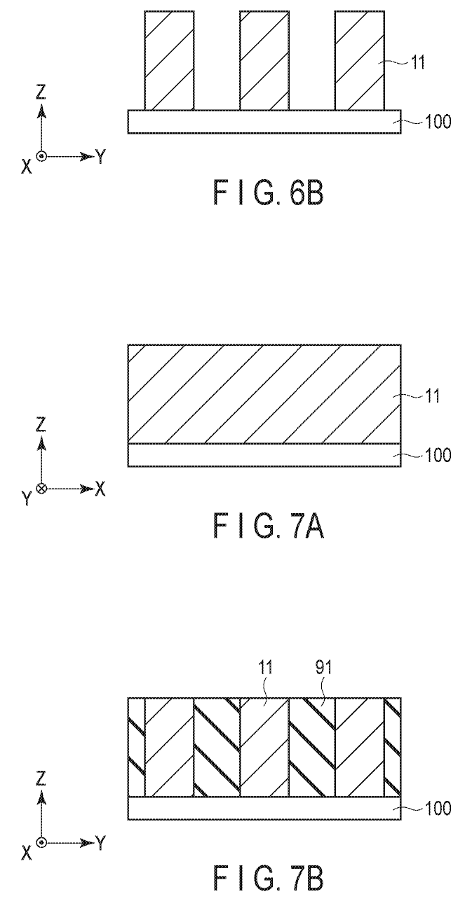

FIGS. 6A and 6B to FIGS. 15A and 15B are cross-sectional diagrams schematically illustrating the method of manufacturing the magnetic memory device of this embodiment. FIGS. 6A through 15A are cross sections parallel to the X direction, and FIGS. 6B through 15B are cross sections parallel to the Y direction.

First, as shown in FIGS. 6A and 6B, a line pattern of the first conductive layer 11 is formed on the lower structure 100 including a semiconductor substrate (not shown). A tungsten (W) layer is used for the first conductive layer 11.

Then, as shown in FIGS. 7A and 7B, the interlayer insulating layer 91 is formed on the structure obtained by the processing step shown in FIGS. 6A and 6B. Further, the interlayer insulating layer 91 is subjected to chemical mechanical polishing (CMP) to fill the area between adjacent first conductive layers 11 with the interlayer insulating layer 91.

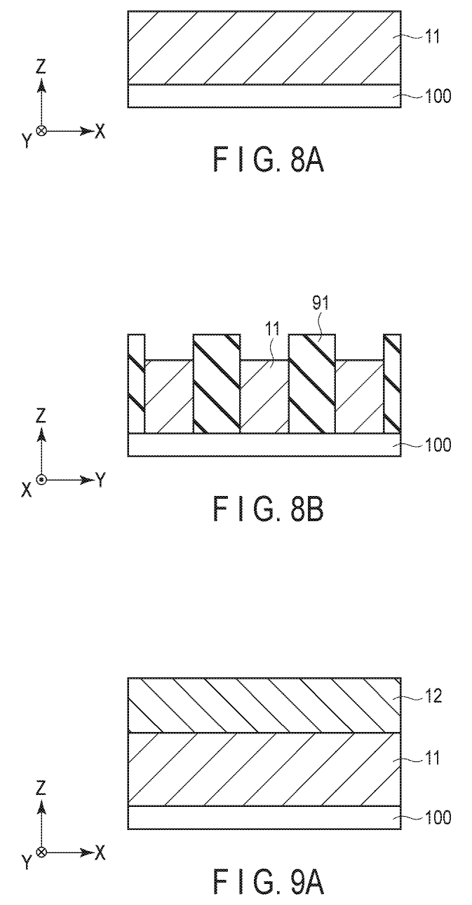

Subsequently, as shown in FIGS. 8A and 8B, the first conductive layer 11 is subjected to etching-back to form trenches.

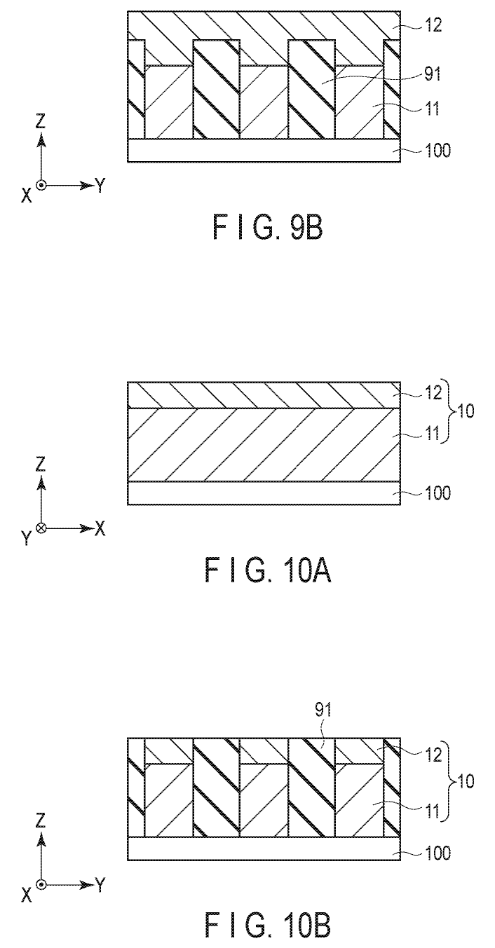

After that, as shown in FIGS. 9A and 9B, a carbon (C) layer is formed as the second conductive layer 12 on the structure obtained by the processing step shown in FIGS. 8A and 8B.

Next, as shown in FIGS. 10A and 10B, CMP is performed on the second conductive layer 12 to fill the trenches obtained in the processing step of FIGS. 8A and 8B with the second conductive layer 12. In this manner, the first wiring lines 10 formed from the first conductive layer 11 and the second conductive layer 12 is obtained. The first wiring lines 10 extends in the X direction.

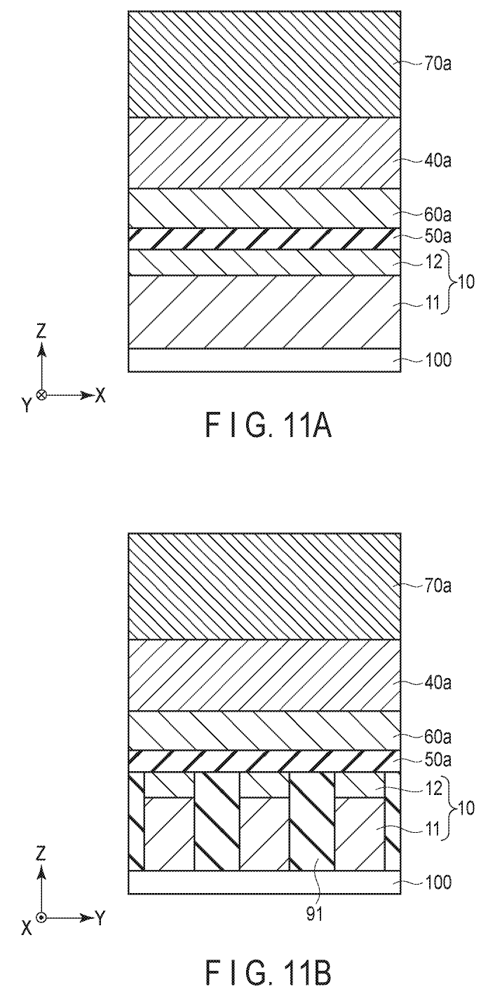

Then, as shown in FIGS. 11A and 11B, a selector layer (specifically, a selector material layer) 50a, a middle electrode layer 60a, a magnetoresistance effect element layer 40a and a hard mask layer 70a are formed on the structure obtained in the processing step of FIGS. 10A and 10B.

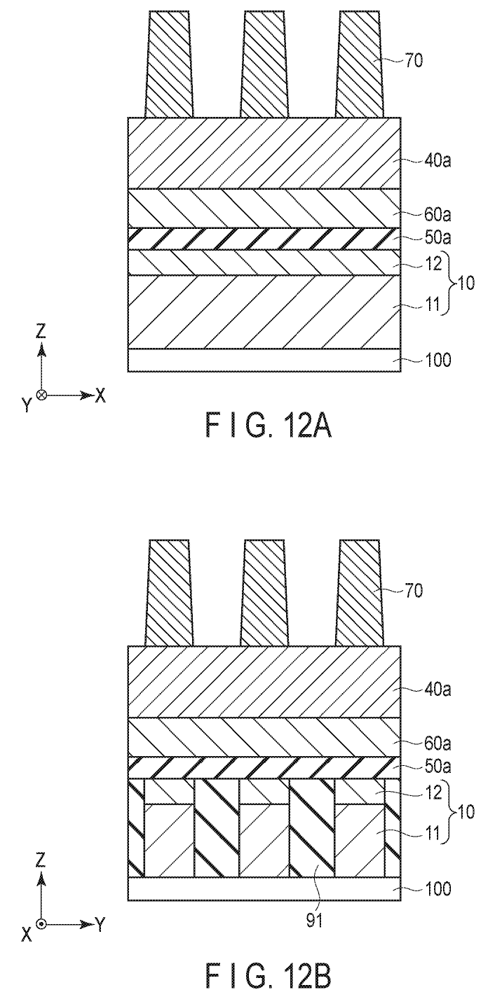

Subsequently, as shown in FIGS. 12A and 12B, the hard mask layer 70a is patterned to form a pattern of the hard mask 70.

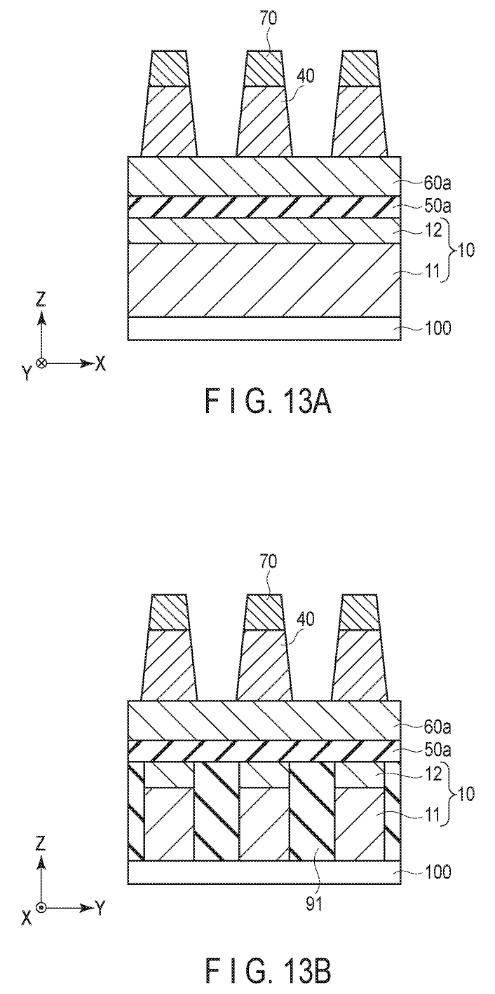

After that, as shown in FIG. 13A and FIG. 13B, using the hard mask 70 as a mask, the magnetoresistance effect element layer 40a is etched by ion beam etching (IBE). Thus, a pattern of the magnetoresistance effect element 40 is obtained. Here, the thickness of the hard mask 70 is reduced by IBE.

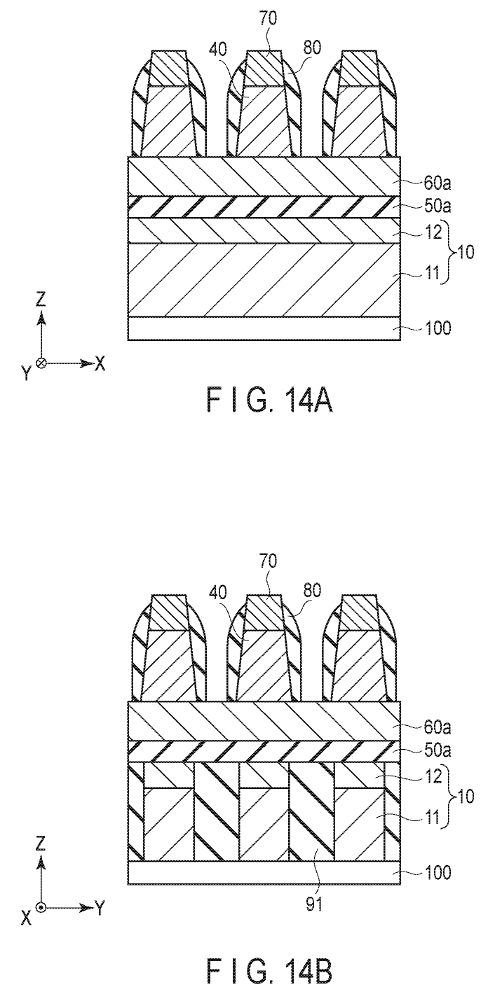

Next, as shown in FIGS. 14A and 14B, the sidewall insulating layer 80 is formed on the side surface of the magnetoresistance effect element layer 40 and the side surface of the hard mask 70.

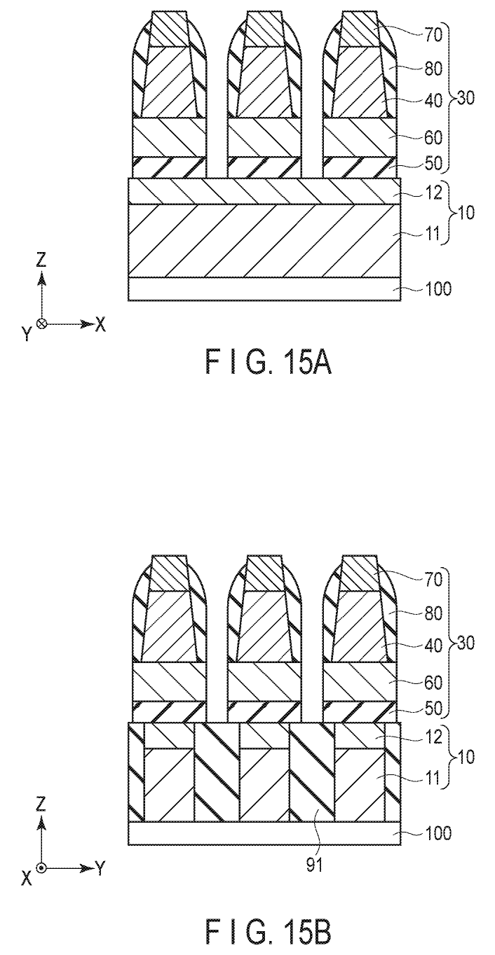

Then, as shown in FIGS. 15A and 15B, using the magnetoresistance effect element 40, the hard mask 70 and the sidewall insulating layer 80 as masks, the selector layer 50a and the middle electrode layer 60a are etched by reactive ion etching (RIE). Thus, patterns of the selector 50 and the middle electrode 60 can be obtained.

It should be noted here that the surface of the second conductive layer 12 may be exposed by the RIE process shown in FIGS. 15A and 15B, and the carbon (C) contained in the second conductive layer 12 may be attached to the side surface of the selector 50. As a result, the thus attached carbon may cause leakage. However, the etching rate of the carbon layer used for the second conductive layer 12 is sufficiently low as compared to that of the selector material layer of the selector 50. With this configuration, the second conductive layer (carbon layer) 12 is not substantially etched by the RIE process, and the amount of carbon attached to the side surface of the selector 50 is very small. Further, by performing oxygen ashing after the RIE, the carbon attached to the side surface of the selector 50 can be easily removed.

After the processing step shown in FIGS. 15A and 15B, the interlayer insulating layer 92 is formed, and further, the second wiring line 20 and the interlayer insulating layer 93 are formed, thereby obtaining the configuration shown in FIGS. 2A and 2B.

As described above, in this embodiment, the first wiring lines 10 each include a first conductive layer 11 and a second conductive layer 12 provided on the first conductive layer 11, and the second conductive layer 12 is formed from a carbon (C) layer. If the second conductive layer (carbon layer) 12 is not provided, the metal material of the first wiring lines 10 may attach to the side surface of the selector 50 during the RIE process shown in FIGS. 15A and 15B, and the attached metal material may become a major cause of leakage.

In this embodiment, the second conductive layer (carbon layer) 12 is included in the first wiring lines 10, and therefore it is possible to prevent the material of the first wiring lines 10 from attaching to the side surface of the selector 50 and causing leakage.

Further, when the first wiring lines 10 is formed from the second conductive layer (carbon layer) 12 only, the resistance of the first wiring lines 10 may undesirably become high. In this embodiment, the first wiring lines 10 include the first conductive layer 11 formed of a metal material having low resistance. Therefore, the resistance of the first wiring lines 10 can be lowered.

Therefore, in this embodiment, it is possible to obtain a magnetic memory device with excellent characteristics, which can suppress leakage of the selector 50 and can lower the resistance of the first wiring lines 10.

Note that in the embodiment described above, the selector 50 is provided on the lower layer side of the magnetoresistance effect element 40, but the selector 50 may as well be provided on the upper layer side of the magnetoresistance effect element 40.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method of manufacturing a magnetic memory device, the method comprising:
forming a first structure including a first wiring line extending in a first direction, the first wiring line including a first conductive layer and a second conductive layer provided on the first conductive layer and formed of a material containing carbon (C);
forming a stacked layer in which a magnetoresistance effect element layer and a switching element layer are stacked, on the first structure;
forming a magnetoresistance effect element and a switching element by etching the magnetoresistance effect element layer and etching the switching element layer; and
forming a second wiring line extending in a second direction intersecting the first direction, on a second structure including the magnetoresistance effect element and the switching element.

2. The method of claim 1, wherein a resistivity of the first conductive layer is lower than a resistivity of the second conductive layer.

3. The method of claim 1, wherein the first conductive layer is formed of a metal material containing a metal element.

4. The method of claim 3, wherein the metal element is tungsten (W) or copper (Cu).

5. The method of claim 1, wherein a pattern of the first conductive layer and a pattern of the second conductive layer are aligned with each other as viewed from the first direction.

6. The method of claim 1, wherein the switching element layer is provided on a lower layer side of the magnetoresistance effect element layer.

7. The method of claim 1, wherein the switching element changes from an off state to an on state when a voltage applied between two terminals thereof becomes equal to or higher than a threshold voltage.

8. The method of claim 1, wherein the switching element layer includes an insulating switching material layer.

9. The method of claim 8, wherein a main ingredient of the insulating switching material layer is silicon oxide.

10. The method of claim 9, wherein the insulating switching material layer contains arsenic (As).

11. The method of claim 1, wherein the magnetoresistance effect element includes a first magnetic layer having a variable magnetization direction, a second magnetic layer having a fixed magnetization direction, and a nonmagnetic layer provided between the first magnetic layer and the second magnetic layer.

12. The method of claim 1, wherein both of the first conductive layer and the second conductive layer extend in the first direction.

13. The method of claim 12, wherein the second conductive layer extends in the first direction along the first conductive layer.

14. The method of claim 1, wherein the first structure further includes a first insulating layer provided along a side surface of the first wiring line and extending in the first direction.

15. The method of claim 14, wherein the forming the magnetoresistance effect element and the switching element includes forming a recess in an upper surface of the first insulating layer by etching a part of the upper surface of the first insulating layer.

16. The method of claim 15, wherein:
the second structure further includes a second insulating layer surrounding a side surface of the magnetoresistance effect element and a side surface of the switching element, and
a portion of the second insulating layer is provided in the recess.

17. The method of claim 1, wherein:
the stacked layer further includes an electrode layer provided between the magnetoresistance effect element layer and the switching element layer, and
the forming the magnetoresistance effect element and the switching element includes forming an electrode by etching the electrode layer.
